(19) United States
(12) Patent Application Publication
(10) Pub. No.: US 2014/0361257 A1
(43) Pub. Date: Dec. 11, 2014

(54) ORGANIC LIGHT EMITTING DIODE DISPLAY

(71) Applicant: Samsung Display Co., Ltd., Yongin-City (KR)

(72) Inventors: TAE-JIN PARK, Yongin-City (KR); Jung-Min Moon, Yongin-City (KR)

(73) Assignee: Samsung Display Co., Ltd., Yongin-City (KR)

(21) Appl. No.: 14/051,909

(22) Filed: Oct. 11, 2013

(30) Foreign Application Priority Data
Jun. 5, 2013 (KR) 10-2013-0064808

(51) Int. Cl. H01L 27/32; H01L 51/50

(52) U.S. Cl. CPC H01L 27/3209; H01L 51/5088; H01L 51/5056
USPC 257/40

(57) ABSTRACT

An organic light emitting diode (OLED) display includes: a first electrode; a hole auxiliary layer formed on the first electrode; a red organic emitting layer, a green organic emitting layer, and a blue organic emitting layer formed on the hole auxiliary layer; a red auxiliary layer and a green auxiliary layer located between the hole auxiliary layer and the red organic emitting layer and between the hole auxiliary layer and the green organic emitting layer, respectively; an electron auxiliary layer formed on the red organic emitting layer, the green organic emitting layer, and the blue organic emitting layer; and a second electrode formed on the electron auxiliary layer. At least one of the red auxiliary layer and the green auxiliary layer includes a charge speed control layer, and a T1 level of the charge speed control layer is relatively higher than that of the organic emitting layer.

### RELATED APPLICATIONS

This application claims priority to Korean Patent Application No. 10-2013-0064808 filed on Jun. 5, 2013, the entire disclosure of which is hereby incorporated by reference herein in its entirety.

### 1. TECHNICAL FIELD

The present disclosure relates generally to an organic light emitting diode (OLED) display.

### 2. DISCUSSION OF THE RELATED ART

In recent years, a device including an organic light emitting diode (OLED) has received attention as a display device and illumination device.

The OLED includes, for example, two electrodes and an emitting layer located therebetween, and excitons are generated by combining electrons provided from one of the two electrodes and holes provided from the other electrode at the emitting layer. Energy is outputted from the excitons to thereby emit light.

The OLED is of a type of device that emits light by itself without an additional light source, so that it may be beneficial in terms of power consumption. Further, the OLED can increase the flexibility characteristic by reducing the thickness and weight of the display device.

A display device including such an OLED may have increased response speed, viewing angle, and contrast ratio.

However, there may be a need to increase the luminous efficiency of OLEDs and the lifespan thereof.

### SUMMARY

Exemplary embodiments of the present invention provide an organic light emitting diode (OLED) display capable of increasing luminous efficiency and increasing the lifespan thereof.

An exemplary embodiment provides an organic light emitting diode (OLED) display including: a first electrode, a hole auxiliary layer disposed on the first electrode, a red organic emitting layer, a green organic emitting layer, and a blue organic emitting layer disposed on the hole an auxiliary layer, a red auxiliary layer disposed between the hole auxiliary layer and the red organic emitting layer, a green auxiliary layer disposed between the hole auxiliary layer and the green organic emitting layer, an electron auxiliary layer disposed on the red organic emitting layer, the green organic emitting layer, and the blue organic emitting layer and a second electrode disposed on the electron auxiliary layer. At least one of the red auxiliary layer and the green auxiliary layer includes a charge speed control layer, and a T1 level of the charge speed control layer is higher than a T1 level of at least one of the red organic emitting layer and the green organic emitting layer.

The charge speed control layer may include a first charge speed control layer disposed on the hole auxiliary layer and a second charge speed control layer disposed on the first charge speed control layer, and a HOMO level of the first charge speed control layer may be lower than a HOMO level of the second charge speed control layer.

The HOMO level may range from 4.5 eV to 6.5 eV, inclusive.

The charge speed control layer may be formed of a biaryl amine or a carbazole core.

The T1 level may be in a range of from about 2.4 eV to about 3.0 eV.

The hole auxiliary layer may include a hole injection layer (HIL) disposed on the first electrode and a hole transport layer (HTL) disposed on the HIL, and the electron auxiliary layer may include an electron transport layer (ETL) disposed on the organic emitting layer and an electron injection layer (EIL) disposed on the ETL.

The OLED display may further include a thin film transistor connected to the first electrode.

In accordance with an exemplary embodiment, an organic light emitting diode (OLED) display is provided. The OLED display includes an insulation substrate disposed in a red pixel configured to display a red color, a green pixel configured to display a green color and a blue pixel configured to display a blue color, a plurality of driving transistors disposed on the insulation substrate in the red pixel, the green pixel and the blue pixel, a protective layer disposed on the driving transistors in the red pixel, the green pixel and the blue pixel, a first electrode disposed on the protective layer in the red pixel, the green pixel and the blue pixel, a pixel defining layer disposed on the protective layer and on an edge of the first electrode, a hole injection layer disposed on the pixel definition layer and on the first electrode in the red pixel, the green pixel, and the blue pixel, a hole transport layer disposed on the hole injection layer in the red pixel, the green pixel and the blue pixel, a red charge speed control layer including a red first charge speed control layer and a red second charge speed control layer sequentially stacked on the hole transport layer in the red pixel, a green charge speed control layer including a green first charge speed control layer and a green second charge speed control layer sequentially stacked on the hole transport layer in the green pixel.

The OLED display further includes a red organic emitting layer disposed on the red charge speed control layer, a green organic emitting layer disposed on the green charge speed control layer, a blue organic emitting layer disposed on the hole transport layer in the blue pixel, an electron transport layer disposed on the red organic emitting layer, the green organic emitting layer and the blue organic emitting layer, an electron injection layer disposed on the electron transport layer in the red pixel, the green pixel and the blue pixel and a second electrode disposed on the electron injection layer in the red pixel, the green pixel and the blue pixel.

A highest occupied molecular orbital (HOMO) level of the red first charge speed control layer is higher than a HOMO level of the red second charge speed control layer and a HOMO level of the green first charge speed control layer is higher than a HOMO level of the green second charge speed control layer.

In accordance with an exemplary embodiment, by forming a light emitting auxiliary layer, it is possible to increase the lifespan characteristic of an organic light emitting element.

### BRIEF DESCRIPTION OF THE DRAWINGS

Exemplary embodiments of the present invention can be understood in more detail from the following detailed description taken in conjunction with the attached drawings, in which:

FIG. 1 is a plan view schematically showing the arrangement of pixels in an organic light emitting diode (OLED) display in accordance with an exemplary embodiment.

FIG. 2 is a schematic cross-sectional view of the OLED display of FIG. 1.

FIG. 3 and FIG. 4 are energy band diagrams in accordance with an exemplary embodiment.

FIG. 5 is a graph showing luminance and luminous efficiency.

FIG. 6 is a graph showing time and luminance.

FIG. 7 is an equivalent circuit of a pixel in the OLED display in accordance with an exemplary embodiment.

FIG. 8 is a cross-sectional view showing three pixels in an OLED display in accordance with an exemplary embodiment.

### DETAILED DESCRIPTION OF EXEMPLARY EMBODIMENTS OF THE INVENTION

In the following detailed description, exemplary embodiments have been shown and described, simply by way of illustration. As those skilled in the art would realize, exemplary embodiments of the present invention may be modified in various different ways, all without departing from the spirit or scope of the present invention.

In the drawings, the thickness of layers, films, panels, regions, etc. may be exaggerated for clarity. Like reference numerals designate like elements throughout the specification. It will be understood that when an element such as a layer, film, region, or substrate is referred to as being “on” another element, it can be directly on the other element or intervening elements may also be present.

As used herein, the singular forms, “a”, “an”, and “the” are intended to include plural forms as well, unless the context clearly indicates otherwise.

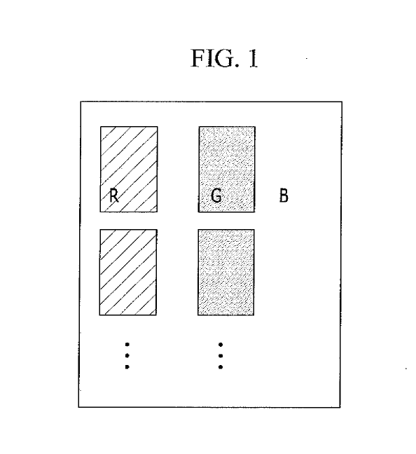

With reference to FIG. 1, an organic light emitting diode (OLED) display will now be described in accordance with an exemplary embodiment.

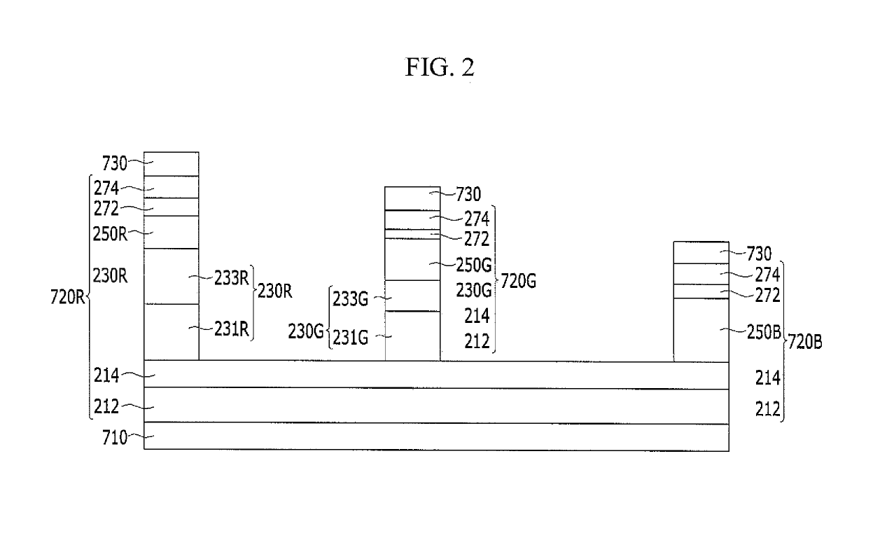

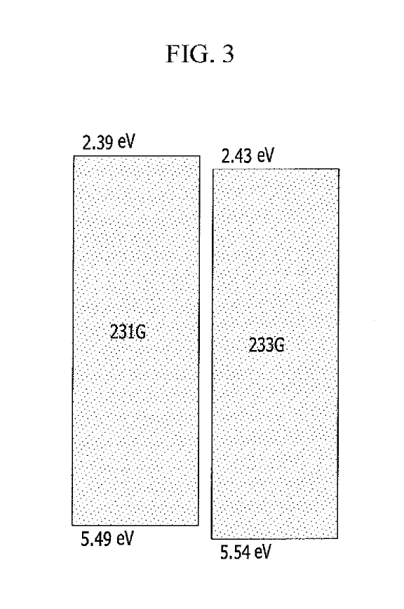

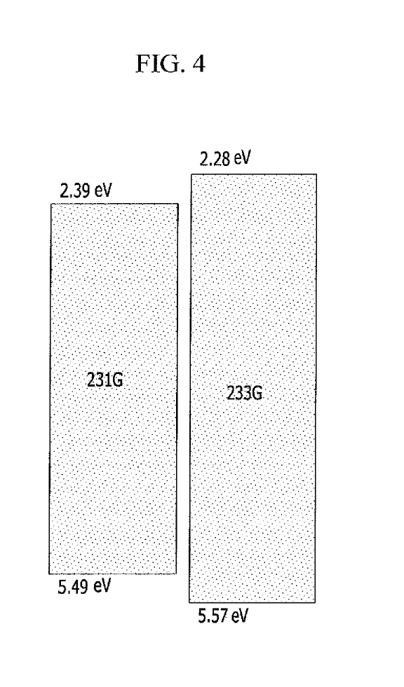

FIG. 1 is a plan view schematically showing the arrangement of pixels in the OLED display in accordance with the exemplary embodiment, and FIG. 2 is a schematic cross-sectional view of the OLED display of FIG. 1. FIG. 3 and FIG. 4 are energy band diagrams in accordance with an exemplary embodiment.

As shown in FIG. 1, the OLED display includes, for example, a red pixel “R” displaying a red color, a green pixel “G” displaying a green color, and a blue pixel “B” displaying a blue color. The red, green, and blue colors may be employed as examples of primary colors for displaying full colors, and the red, green, and blue pixels R, G, and B may be employed as primary pixels for displaying full colors. In the present exemplary embodiment, the three pixels constituting one group are repeatedly arranged according to the row and column.

For example, as for the arrangement of the red, green, and blue pixels, a plurality of red pixels R, a plurality of green pixels G, and a plurality of blue pixels B are alternately arranged according to the row. The red pixel R, the green pixel G, and the blue pixel B may have, for example, substantially equivalent areas.

In FIG. 1, the red pixels R and the green pixels G are shown to be surrounded by the blue pixels B, which indicates that a blue organic emitting layer is formed on the whole area including regions of the blue pixels B. The shape and arrangement of such pixels may be varied, and other pixels displaying a white color and the like may be included.

The pixels of FIG. 1 may include the same layers as shown in FIG. 2.

As shown in FIG. 2, the OLED display includes, for example, a first electrode 710, an organic light emitting member 720R, 720G, and 720B formed on the first electrode 710, and a second electrode 730 formed on the organic light emitting member 720R, 720G, and 720B.

One of the first electrode 710 and the second electrode 730 may be a cathode electrode, and the other electrode may be an anode electrode. For example, the first electrode 710 and the second electrode 730 may be the cathode electrode and the anode electrode, respectively, or vice versa.

At least one of the first electrode 710 and the second electrode 730 may be, for example, a transparent electrode. When the first electrode 710 is the transparent electrode, the bottom emission type may be provided to emit light downward. When the second electrode 730 is the transparent electrode, the top emission type may be provided to emit light upward. Moreover, when both the first electrode 710 and the second electrode 730 are transparent electrodes, it is possible to emit light toward both of the upper and lower sides. The transparent electrode may be formed of, for example, indium tin oxide (ITO), indium zinc oxide (IZO), zinc oxide (ZnO), aluminum-doped zinc oxide (AZO), indium oxide (In₂O₃), tin oxide (SnO₂), or a combination thereof. Alternatively, the transparent electrode may be formed, for example, in a thin thickness by using aluminum (Al), silver (Ag), magnesium (Mg), platinum (Pt), palladium (Pd), gold (Au), nickel (Ni), neodymium (Nd), iridium (Ir), chromium (Cr), lithium (Li), calcium (Ca), or a combination thereof.

When the first electrode 710 or the second electrode 730 is a non-transparent electrode, the non-transparent electrode may be formed of, for example, a non-transparent metal such as aluminum (Al), silver (Ag), magnesium (Mg), platinum (Pt), palladium (Pd), gold (Au), nickel (Ni), neodymium (Nd), iridium (Ir), chromium (Cr), lithium (Li), calcium (Ca), or a combination thereof.

The organic light emitting member 720R, 720G, and 720B includes, for example, an auxiliary layer for increasing the luminous efficiency of organic emitting layers 250R, 250G, and 250B.

For example, referring to FIG. 2, the light emitting member includes a red organic light emitting member 720R, a green organic light emitting member 720G, and a blue organic light emitting member 720B, and the red and green organic light emitting members 720R and 720G include auxiliary layers located on the first electrode 710. The auxiliary layers may have, for example, a multi-layer structure including a hole injection layer (HIL) 212, a hole transport layer (HTL) 214, an electron transport layer (ETL) 272, and an electron injection layer (EIL) 274.

The HIL 212 may be formed of, for example, copper phthalocyanine (CuPc), N,N′-diphenyl-N,N′-di-[4-(N,N-ditolyl-amino)phenyl]benzidine (NTNPB), (poly(3,4-ethylenedioxythiophene)) (PEDOT), polyaniline (PANI), N,N′-diphenyl-N,N′-di[4-(N,N-diphenyl-amino)phenyl]benzidine (NPNPB), or a combination thereof but exemplary embodiments of the present invention are not limited thereto.

The HTL 214 may be formed of, for example, N,N-di(1-naphthyl)-N,N′-di(phenyl)benzidine (NPD), 4,4′,4″-tris(N-3-methylphenyl-N-phenyl-amino)-triphenylamine (MTDATA), N,N′-bis(naphthalen-1-yl]-N,N′-bis(phenyl)-benzidine (NPB), N,N′-bis(3-methylphenyl)-N,N′-bis(phenyl) (TPD), or a combination thereof but exemplary embodiments of the present invention are not limited thereto.

Moreover, at least one of the red organic light emitting member 720R and the green organic light emitting member 720G may include, for example, a multi-layered charge speed control layer 230R (230G).

The charge speed control layer 230R (230G) may include, for example, a first charge speed control layer 231R (231G) and a second charge speed control layer 233R (233G).

In this case, the first charge speed control layer 231R (231G) and the second charge speed control layer 233R (233G) have different hole mobilities, and the highest occupied molecular orbital (HOMO) level of the first charge speed control layer 231R (231G) is higher than that of the second charge speed control layer 233R (233G). High HOMO levels indicate closer to a vacuum level based on the vacuum level.

Referring to FIG. 3, in an exemplary embodiment, as the HOMO level of the second charge speed control layer 233G is relatively lower than that of the first charge speed control layer 231G, the speed of holes is reduced by the second charge speed control layer 233G.

In other words, as the holes and the electrons have different moving speeds and the moving speed of the holes is quicker than that of the electrons, some holes may remain as excessive holes to disappear in the emitting layer.

However, in the present exemplary embodiment, as the HOMO level of the second charge speed control layer 233G is relatively lower than that of the first charge speed control layer 231G, it is possible to reduce the speed at which the holes are transferred to the emitting layer.

By controlling the difference in the HOMO levels of the first charge speed control layer 231G and the second charge speed control layer 233G, it is possible to adjust the moving speed of holes depending on the moving speed of electrons. Accordingly, the disappearing excessive holes can be used for the light emission, thereby increasing the light emitting lifespan of the emitting layer.

For example, in this case, the HOMO level may range from about 4.5 eV to about 6.5 eV and the charge speed control layers 230R and 230G may include a compound containing, e.g., a biaryl amine core or a carbazole core.

In the meantime, referring to FIG. 4, the T1 level (triplet energy level) of the second charge speed control layer 233G in accordance with the present exemplary embodiment has, for example, a relatively higher value than the T1 level of the emitting layer.

When the T1 level of the second charge speed control layer 233G has a value that is higher than the T1 level of the emitting layer, the electrons transferred into the emitting layer can be prevented from moving out to the HTL.

Here, for example, in the present embodiment, the T1 level may range from about 2.4 eV to about 3.0 eV, and the charge speed control layers 230R and 230G may include, for example, a compound containing a biaryl amine core or a carbazole core.

Accordingly, in the present embodiment, the number of electrons existing within the emitting layer is increased, thereby increasing the light emitting lifespan.

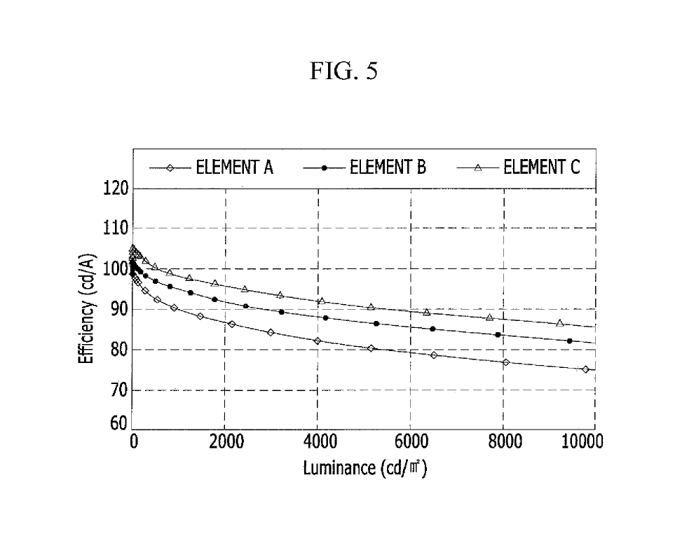

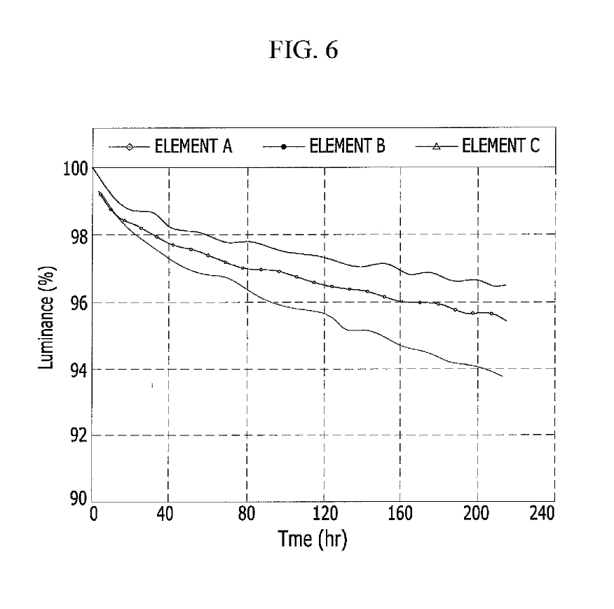

FIG. 5 is a graph showing luminance and efficiency, and FIG. 6 is a graph showing time and luminance.

In FIG. 5 and FIG. 6, an element “A” indicates an organic light emitting element according to the conventional art, and an element “B” indicates an organic light emitting element having an energy band of FIG. 3. An element “C” indicates an organic light emitting element having an energy band of FIG. 4.

Referring to FIG. 5, it can be determined that the efficiency of the element A drops by about 10% or more as compared with those of elements B and C.

Referring to FIG. 6, it can be determined that the luminance of the element A drops according to the time at a quicker speed than those of the elements B and C, and the luminances of the elements B and C are respectively increased by about 30% and about 40%, respectively as compared with the element A.

For example, referring to FIG. 2 again, the emitting layer may be formed of an organic material or a mixture of an organic material and an inorganic material that uniquely emits light of one color among primary colors such as the three primary colors of red, green, and blue. Moreover, to prevent colors from being mixed, it is possible to use an organic light emitting material in which the hole mobilities of hosts of the red organic emitting layer 250R and the green organic emitting layer 250G are, for example, smaller than that of a host of the blue organic emitting layer 250B and to adjust the thicknesses of the organic emitting layers 250R, 250G, and 25013 appropriately, such that light can be emitted by combining the electrons and the holes at the red organic emitting layer 250R and the green organic emitting layer 250G in the red pixels R and the green pixels G.

The red and green organic emitting layers 250R and 250G may include, for example, a phosphorescent host, a fluorescent host, a phosphorescent dopant, and a fluorescent dopant.

An example of such a host may include 4,4′-bis(carbazol-9-yl)biphenyl (CBP), 9,10-di(naphth-2-yl)anthracene (ADN), 1,3,5-tris(N-phenylbenzimiazole-2-yl)benzene (TPBI), 2-tert-butyl-9,10-di(2-naphthyl)anthracene (TBADN), 1,3-bis(carbazol-9-Abenzene (MCP), 1,3,5-tris(carbazol-9-yl)benzene (TCP), or a combination thereof but exemplary embodiments of the present invention are not limited thereto.

An example of a red dopant may include Pt(II) octaethylporphine (PtOEP), tris(1-phenylisoquinoline)iridium(III) (Ir(piq)₃), bis(2-benzo[b]thiophen-2-yl-pyridine(Ir(btp)₂(acac)), or a combination thereof but exemplary embodiments of the present invention are not limited thereto. An example of a green dopant may include tris(2-phenylpyridine)iridium (Ir(ppy)₃), or acetylacetonatobis(2-phenylpyridine)iridium(Ir(ppy)₂(acac)), and an example of a blue dopant may include bis[2-(4,6-difluorophenyl)pyridinato-N,C2′]iridium picolinate (F₂Irpic), (F₂ ppy)₂Ir(tmd), tris[1-(4,6-difluorophenyl)pyrazolate-N,C2′]iridium) (Ir(dfppz)₃), 4,4′-bis(2,2-diphenylvinyl)-1,1′-biphenyl) (DPVBi), 4,4-bis[4-(di-p-tolylamino)styryl]biphenyl (DPAVBi), 2,5,8,11-tetra-tert-butylperylene (TBPe), or a combination thereof but exemplary embodiments of the present invention are not limited thereto. The blue organic emitting layer 250B is located, for example, on the front surface of a substrate including the green organic emitting layer 250G and the red organic emitting layer 250R, and the ETL 272 and the EIL 274 are sequentially stacked on the front surface of the blue organic emitting layer 250B.

Each of the ETL 272 and the EIL 274 may be formed to include, for example, at least one of Alq3(tris(8-hydroxyquinolino)aluminum), PBD, TAZ, spiro-PBD, BAIq, SAIq, 2,9-dimethyl-4,7-diphenyl-1,10-phenanthroline(BCP), and 4,7-diphenyl-1,10-phenanthroline (Bphen), but exemplary embodiments of the present invention are not limited thereto.

The HIL 212, the HTL 214, the ETL 272, and the EIL 274 may increase the luminous efficiency of the organic emitting layers 250R, 250G, and 250B. For example, the HTL 214 and the ETL 272 may keep a balance between the electrons and the holes, and the HIL 212 and the EIL 274 may increase the injection of the electrons and the holes.

The second electrode 730 is formed on the EIL 274.

For example, the second electrode 730 is formed in a dual-layered structure including a lower layer and an upper layer, and has a transflective characteristic that reflects some of the light and transmits the other. Although each of the lower layer and the upper layer is formed of a metal having a reflective characteristic that reflects light, these layers may have the transflective characteristic that reflects or transmits incident light by reducing their thickness. Moreover, the second electrode 730 may be formed of, for example, a single film.

Hereinafter, an OLED display including the aforementioned organic light emitting element will be described in detail.

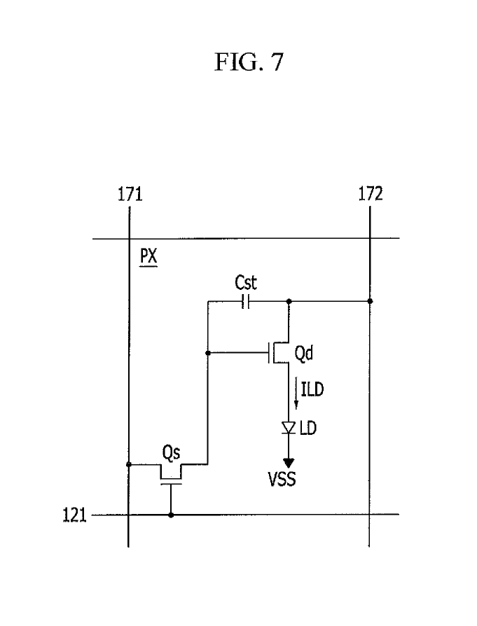

FIG. 7 is an equivalent circuit of a pixel in the OLED display in accordance with an exemplary embodiment.

Referring to FIG. 7, in accordance with the present exemplary embodiment, the OLED display includes, for example, a plurality of signal lines 121, 171, and 172 and pixels PX connected thereto. One pixel PX may be, for example, any one of the red pixel R, the green pixel G, and the blue pixel B shown in FIG. 1.

The signal lines include, for example, scan signal lines 121 for transferring gate signals (or scan signals), data lines 171 for transferring data signals, driving voltage lines 172 for transferring driving voltages, and the like. The scan signal lines 121 extend, for example, substantially in a row direction and substantially parallel with each other, and the data lines 171 extend, for example, substantially in a column direction and substantially parallel with each other. The driving voltage lines 172 are shown to extend, for example, substantially in a column direction, but they may extend, for example, in the row direction or the column direction, and may be formed in a mesh shape.

One pixel PX includes, for example, a switching transistor Qs, a driving transistor Qd, a storage capacitor Cst, and an organic light emitting element LD.

The switching transistor Qs has, for example, a control terminal connected to the corresponding gate line 121, an input terminal connected to the corresponding data line 171, and an output terminal connected to the driving transistor Qd. The switching transistor Qs transmits a data signal transferred from the data line 171 to the driving transistor Qd in response to a gate signal transferred from the gate line 121.

The driving transistor Qd also has, for example, a control terminal connected to the switching transistor Qs, an input terminal connected to the driving voltage line 172, and an output terminal connected to the organic light emitting element LD. The driving transistor Qd flows an output current ILD having a magnitude depending on the voltage between the control terminal and the output terminal thereof.

The capacitor Cst is connected, for example, between the control terminal and the input terminal of the driving transistor Qd. The capacitor Cst charges a data signal applied to the control terminal of the driving transistor Qd and maintains the charging of the data signal even after the switching transistor Qs is turned off.

The organic light emitting element LD as an OLED has an anode connected to the output terminal of the driving transistor Qd and a cathode connected to a common voltage Vss. The organic light emitting element LD emits light having an intensity depending on an output current ILD of the driving transistor Qd, thereby displaying images. The organic light emitting element LD may include an organic material uniquely emitting light of at least one color among primary colors such as the three primary colors of red, green, and blue, and the organic light emitting device displays desired images by spatial sums thereof.

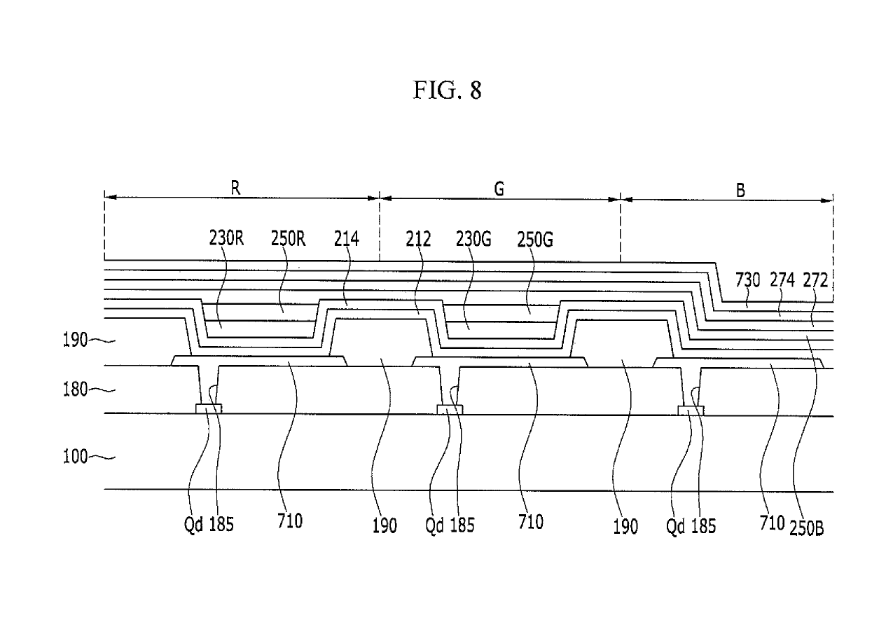

Hereinafter, a cross-sectional structure of the OLED display will be described with reference to FIG. 2 and FIG. 8 in accordance with an embodiment.

FIG. 8 is a cross-sectional view showing three pixels in OLED display in accordance with an exemplary embodiment.

For example, as shown in FIG. 8, in the OLED display in accordance with the present exemplary embodiment, a plurality of driving transistors Qd are formed on an insulation substrate 100 that may be made of transparent glass, plastic, quartz, or the like. For example, in an exemplary embodiment, the insulation substrate 100 may be a flexible substrate. Suitable materials for the flexible substrate include, for example, polyethersulfone (PES), polyethylenenaphthalate (PEN), polyethylene (PE), polyimide (PI), polyvinyl chloride (PVC), polyethylene terephthalate (PET), or combinations thereof.

In addition, a plurality of signal lines (not shown), a plurality of switching transistors (not shown), and the like may be further formed on the insulation substrate 100.

A protective layer 180 that may be made of, for example, an inorganic material or an organic material is formed on the driving transistor Qd. For example, in an embodiment, the protective layer 180 may be formed with a polyacryl or polyimide-based organic material. In the case where the protective layer 180 is made of the organic material, a surface thereof may be, for example, flat.

A contact hole 185 through which a portion of the driving transistor Qd is exposed is formed in the protective layer 180.

The first electrode 710 is formed on the protective layer 180 of each pixel R, G, and B. The first electrode 710 may be an anode electrode of FIG. 7. The first electrode 710 may be made of, for example, a transparent conductive oxide such as ITO (indium tin oxide), IZO (indium zinc oxide), zinc oxide (ZnO), aluminum-doped zinc oxide (AZO), indium oxide (In₂O₃), tin oxide (SnO₂), or a combination thereof.

The first electrode 710 may further include, for example, a reflection layer (not shown) made of a reflective material, and the reflection layer may be made of, for example, a metal having high reflectivity such as silver (Ag), aluminum (Al), magnesium (Mg), platinum (Pt), palladium (Pd), gold (Au), nickel (Ni), neodymium (Nd), iridium (Ir), chromium (Cr), lithium (Li), calcium (Ca), or an alloy thereof.

A pixel definition layer 190 for covering the circumference of an edge of the first electrode 710 is formed on the protective layer 180. For example, in an exemplary embodiment, the pixel definition layer 190 may be formed with a polyacryl or polyimide-based resin.

In the red, green, and blue pixels R, G, and B, the HIL 212 and the HTL 214 are sequentially stacked on the front surface of the first electrode 710.

Charge speed control layers 230R and 230G are respectively formed on the HTLs 214 of the red pixel R and the green pixel G.

The red and green organic emitting layers 250R and 250G are formed on the charge speed control layers 230R and 230G, respectively, and the blue organic emitting layer 250B is formed on the HTL 214. The red, green, and blue organic emitting layers may respectively be made of, for example, organic materials that uniquely emit light of red, green, and blue colors.

The second electrode 730 is formed on the EIL 274 to transfer a common voltage Vss. The second electrode 730 is formed in, for example, a dual-layered structure including a lower layer and an upper layer, and has a transflective characteristic that reflects some of the light and transmits the rest. Although each of the lower layer and the upper layer is formed of a metal having a reflective characteristic that reflects the light, these layers may have the transflective characteristic that reflects or transmits incident light by reducing their thickness. Moreover, in an embodiment, the second electrode 730 may alternatively be formed of, for example, a single film.

An encapsulation layer (not shown) is, for example, formed on the second electrode 730. The encapsulation layer encapsulates the organic light emitting member 720R, 720G, and 720B and the second electrode 730 to prevent permeation of external moisture or oxygen.

In the OLED display, the first electrode 710, the organic light emitting member 720R, 720G, and 720B, and the second electrode 730 constitute the organic light emitting element LD. The first electrode 710 receives a voltage from the driving transistor (Qd) through the contact hole 185 of the protective layer 180.

The OLED display transmits light to the second electrode 730 to display the image. When the light outputted from the organic light emitting layers 250R, 250G, and 25013 to the second electrode 730 reaches the second electrode 730, some of the light is transmitted through the second electrode 730, and the rest is reflected toward the first electrode 710. The first electrode 710 also reflects the light toward the second electrode 730. As such, interference is generated by the light traveling between the first electrode 710 and the second electrode 730. While the light with a wavelength of the distance between the first electrode 710 and the second electrode 730 that may cause resonance generates constructive interference to increase intensity, the light with other wavelengths generates destructive interference to reduce the intensity. By such traveling and interference of the light, a microcavity effect is caused.

In an exemplary embodiment, it is possible to increase the life-span and efficiency and the microcavity effect by using the auxiliary layer.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. An organic light emitting diode (OLED) display, comprising:
a first electrode;
a hole auxiliary layer disposed on the first electrode;
a red organic emitting layer, a green organic emitting layer, and a blue organic emitting layer disposed on the hole auxiliary layer;
a red auxiliary layer disposed between the hole auxiliary layer and the red organic emitting layer;
a green auxiliary layer disposed between the hole auxiliary layer and the green organic emitting layer;
an electron auxiliary layer disposed on the red organic emitting layer, the green organic emitting layer, and the blue organic emitting layer; and
a second electrode disposed on the electron auxiliary layer,
wherein at least one of the red auxiliary layer and the green auxiliary layer includes a charge speed control layer, and
wherein a triplet energy level (T1) level of the charge speed control layer is higher than a T1 level of at least one of the red organic emitting layer and the green organic emitting layer.

2. The OLED display of claim 1, wherein the charge speed control layer includes:
a first charge speed control layer disposed on the hole auxiliary layer; and
a second charge speed control layer disposed on the first charge speed control layer, and
wherein a highest occupied molecular orbital (HOMO) level of the first charge speed control layer is higher than a HOMO level of the second charge speed control layer.

3. The OLED display of claim 2, wherein the HOMO level is in a range of from about 4.5 eV to about 6.5 eV.

4. The OLED display of claim 3, wherein the charge speed control layer comprises a compound including a biaryl amine core or a carbazole core.

5. The OLED display of claim 1, wherein the T1 level is in a range of from about 2.4 eV to about 3.0 eV.

6. The OLED display of claim 1, wherein the hole auxiliary layer includes:
a hole injection layer (HIL) disposed on the first electrode, and
a hole transport layer (HTL) disposed on the HIL, and
wherein the electron auxiliary layer includes:
an electron transport layer (ETL) disposed on the organic emitting layer, and
an electron injection layer (EIL) disposed on the ETL.

7. The OLED display of claim 1, further comprising
a thin film transistor connected to the first electrode.

8. An organic light emitting diode (OLED) display, comprising:
an insulation substrate disposed in a red pixel configured to display a red color, a green pixel configured to display a green color and a blue pixel configured to display a blue color;
a plurality of driving transistors disposed on the insulation substrate in the red pixel, the green pixel and the blue pixel;
a protective layer disposed on the driving transistors in the red pixel, the green pixel and the blue pixel;
a first electrode disposed on the protective layer in the red pixel, the green pixel and the blue pixel;
a pixel definition layer disposed on the protective layer and on an edge of the first electrode;
a hole injection layer disposed on the pixel defining layer and on the first electrode in the red pixel, the green pixel, and the blue pixel;
a hole transport layer disposed on the hole injection layer in the red pixel, the green pixel and the blue pixel;
a red charge speed control layer including a red first charge speed control layer and a red second charge speed control layer sequentially stacked on the hole transport layer in the red pixel;
a green charge speed control layer including a green first charge speed control layer and a green second charge speed control layer sequentially stacked on the hole transport layer in the green pixel;
a red organic emitting layer disposed on the red charge speed control layer;
a green organic emitting layer disposed on the green charge speed control layer;
a blue organic emitting layer disposed on the hole transport layer in the blue pixel;
an electron transport layer disposed on the red organic emitting layer, the green organic emitting layer and the blue organic emitting layer;
an electron injection layer disposed on the electron transport layer in the red pixel, the green pixel and the blue pixel; and
a second electrode disposed on the electron injection layer in the red pixel, is the green pixel and the blue pixel,
wherein a highest occupied molecular orbital (HOMO) level of the red first charge speed control layer is higher than a HOMO level of the red second charge speed control layer and wherein a HOMO level of the green first charge speed control layer is higher than a HOMO level of the green second charge speed control layer.

9. The OLED display of claim 8, wherein a triplet energy level (T1) of the green second charge speed control layer is higher than a T1 level of the green organic emitting layer and wherein the T1 of the red second charge speed control layer is higher than a T1 level of the red organic emitting layer.

10. The OLED display of claim 9, wherein the HOMO levels are in a range of from about 4.5 eV to about 6.5 eV and wherein the T1 levels are in a range of from about 2.4 eV to about 3.0 eV.

11. The OLED display of claim 10, wherein the red charge speed control layer and the green charge speed control layer each comprise a compound including a biaryl amine core or a carbazole core.

12. The OLED display of claim 9, wherein the hole injection layer comprises at least one of copper phthalocyanine (CuPc), N,N′-diphenyl-N,N′-di-[4-(N,N-ditolyl-amino)phenyl]benzidine (NTNPB), (poly(3,4-ethylenedioxythiophene)) (PEDOT), polyaniline (PANI), and N,N′-diphenyl-N,N′-di-[4-(N,N-diphenyl-amino)phenyl]benzidine (NPNPB).

13. The OLED display of claim 12, wherein the hole transport layer comprises at least one of N,N-di(1-naphthyl)-N,N-di(phenyl)benzidine (NPD), 4,4′,4″-tris(N-3-methylphenyl-N-phenyl-amino)-triphenylamine (MTDATA), N,N′-bis(naphthalen-1-yl]-N,N′-bis(phenyl)-benzidine (NPB), and N,N′-bis(3-methylphenyl)-N,N′-bis(phenyl) (TPD).

14. The OLED display of claim 13, wherein each of the electron transport layer and the electron injection layer comprise at least one of Alq3(tris(8-hydroxyquinolino)aluminum), PBD, TAZ, spiro-PBD, BAIq, SAIq, 2,9-dimethyl-4,7-diphenyl-1,10-phenanthroline(BCP), and 4,7-diphenyl-1,10-phenanthroline (Bphen).

15. The OLED display of claim 8, wherein the first electrode is configured to receive a voltage from the driving transistors through a contact hole in the protective layer.

16. The OLED display of claim 8, wherein the first electrode is a transparent electrode and wherein the OLED display is a bottom emission type.

17. The OLED display of claim 8, wherein the second electrode is a transparent electrode and wherein the OLED display is a top emission type.

18. The OLED display of claim 8, wherein the first electrode and the second electrode are each a transparent electrode.

19. The OLED display of claim 18, wherein the first electrode and the second electrode comprise at least one material selected from the group consisting of indium tin oxide (ITO), indium zinc oxide (IZO), zinc oxide (ZnO), aluminum-doped zinc oxide (AZO), indium oxide (In₂O₃), and tin oxide (SnO₂).

20. The OLED display of claim 8, wherein the first electrode is a transparent electrode comprising a material selected from the group consisting of indium tin oxide (ITO), indium zinc oxide (IZO), zinc oxide (ZnO), aluminum-doped zinc oxide (AZO), indium oxide (In₂O₃), and tin oxide (SnO₂) and wherein the second electrode is a non-transparent electrode comprising at least one material selected from the group consisting of aluminum (AI), silver (Ag), magnesium (Mg), platinum (Pt), palladium (Pd), gold (Au), nickel (Ni), neodymium (Nd), iridium (Ir), chromium (Cr), lithium (Li), and calcium (Ca).
